(19) United States
(12) Patent Application Publication
(10) Pub. No.: US 2006/0145238 A1
(43) Pub. Date: Jul. 6, 2006

(54) Diode structure for word-line protection in a memory circuit

(76) Inventors: Fabiano Fontana, San Jose, CA (US); Steven Fong, Santa Clara, CA (US); Sunil Mehta, San Jose, CA (US); Yongzhong Hu, Cupertino, CA (US)

Correspondence Address: MENDELSOHN AND ASSOCIATES, P.C., 1500 JOHN F. KENNEDY BLVD., SUTIE 405, PHILADELPHIA, PA, 19102, US

(21) Appl. No.: 11/029,950

(22) Filed: Jan. 5, 2005

(51) Int. Cl. H01L 29/788

(52) U.S. Cl. 257/315

(57) ABSTRACT

One embodiment of the invention is an integrated circuit having: (i) an array of flash transistors formed on a substrate and arranged in one or more rows, each flash transistor having a control gate, wherein, in each row, the control gates are connected to a word line; and (ii) for each word line, at least one diode structure formed on the substrate and having first and second diodes, each diode having a cathode and an anode, wherein the word line is connected to the cathode of the first diode and to the anode of the second diode.

### TECHNICAL FIELD

The present invention relates to the field of electronic data storage devices and, more specifically, to circuits/structures adapted to reduce adverse side effects of plasma processing during fabrication of such devices.

### BACKGROUND

A flash memory is a non-volatile data storage device having a plurality of flash transistors (memory cells) that are typically arranged in rows and columns. A typical flash transistor has a source, a drain, a floating gate, and a control gate. The control gates of flash transistors in the same row are electrically connected to a common word line. The drains of flash transistors in a column are electrically connected to a common bit line, and the sources of flash transistors in that column are electrically connected to a common source line. By applying appropriate voltages to the word lines, bit lines, and source lines of the flash memory, data can be written to and read from the flash memory.

FIG. 1 shows a cross-sectional view of a representative flash transistor 100 formed on a p-type silicon substrate 110. An n-type source region 120 and an n-type drain region 130 are formed integrally within substrate 110, and a relatively thin (tunnel) silicon oxide layer is interposed between a top surface of the substrate and a poly-silicon floating gate 140. A poly-silicon control gate 150 is separated from floating gate 140 by a dielectric (e.g., oxide-nitride-oxide (ONO)) layer. Source region 120, drain region 130, and control gate 150 are connected to a source line SL, a bit line BL, and a word line WL, respectively. Since floating gate 140 is surrounded on all sides by dielectric layers, electrical access to the floating gate is only through a capacitor network formed by these dielectric layers and the conducting portions of the source, drain, and control-gate regions. Due to the inherent energy barrier created by the dielectric layers, floating gate 140 is capable of retaining any charge present on the floating gate substantially indefinitely, thereby enabling flash transistor 100 to serve as a non-volatile memory element.

In a typical configuration, flash transistor 100 is programmed as follows. Multiple voltage pulses of approximately +10 V are applied to control gate 150 while the voltage applied to drain region 130 is set to about +6 V and source region 120 is grounded. The relatively high gate voltage inverts the channel in substrate 110 between source region 120 and drain region 130, while the relatively high drain voltage accelerates electrons in the channel region toward the drain regions. Some of the accelerated electrons experience collisions with atoms of the silicon lattice and are scattered toward floating gate 140. Some of the scattered electrons (having enough energy to surmount the potential energy barrier between substrate 110 and floating gate 140) enter the floating gate and are trapped therein. When programming is completed, electrons have been added to floating gate 140, thereby increasing the threshold voltage for flash transistor 100 (i.e., the control-gate voltage at which the flash transistor begins to pass current).

To remove electrons from floating gate 140 (erase transistor 100), multiple voltage pulses of approximately −10 V are applied to control gate 150, while the voltage applied to source region 120 is set to about +6 V and drain region 120 is floating. Under these bias conditions, a relatively strong electric field of about 10 MV/cm is present between floating gate 140 and source region 120, which extracts electrons from the floating gate through the tunnel oxide layer into the source region by way of Fowler-Norheim (F-N) tunneling. When erase is completed, electrons have been removed from floating gate 140, thereby decreasing the threshold voltage for flash transistor 100.

FIG. 2 graphically illustrates a read operation for flash transistor 100, during which the amount of charge present in floating gate 140 is determined and interpreted as binary data. More specifically, FIG. 2 shows current-voltage characteristics of flash transistor 100 in the programmed and erased states. In the erased state, flash transistor 100 has a relatively low threshold voltage Vₜₑ. Above Vₜₑ, the drain current increases approximately linearly with the increase of the control-gate voltage. In the programmed state, flash transistor 100 has a relatively high threshold voltage Vₜₚ. Above Vₜₚ, the drain current again increases approximately linearly with the increase of the control-gate voltage. At a read voltage Vᵣ>Vₜₚ, in either state, non-zero current flows between the source and drain regions of flash transistor 100. During a read operation, this current is sensed and measured by comparing its magnitude with that of a reference current generated in a similarly biased reference cell. When the drain current in flash transistor 100 is greater than the reference current, the flash transistor is interpreted to be in the erased state and have a binary “1”. Similarly, when the drain current in flash transistor 100 is lower than the reference current, the flash transistor is interpreted to be in the programmed state and have a binary “0”.

Flash transistor 100 is usually a part of a relatively large array of similar flash transistors, all of which are implemented in an integrated circuit (IC). Although different fabrication techniques can potentially be used to manufacture such an IC, with the decreasing feature size and use of low-k dielectrics and copper metallization, plasma processing has become the technique of choice for certain fabrication steps. For example, plasma processing is currently used in fine-line pattern definition, high aspect-ratio etching, planarization, resist stripping, etc. However, one problem with plasma processing for an IC having an array of flash transistors 100 is that it typically causes uncontrolled charging of floating gates 140 and/or degradation of the dielectric regions adjacent to the floating gates. This charging/degradation might result in a relatively large threshold-voltage variation across the transistor array in the IC. Due to this variation, it might become difficult to determine and set optimal control-gate voltages for carrying out the above-described program, erase, and read operations in the array.

### SUMMARY

According to one embodiment, the present invention is an integrated circuit having (i) a transistor formed on a substrate and having a control gate connected to a word line; and (ii) a diode structure formed on the substrate and having first and second diodes, each diode having a cathode and an anode, wherein the word line is connected to the cathode of the first diode and to the anode of the second diode.

According to another embodiment, the present invention is a method of fabricating an integrated circuit on a wafer, the method including the acts of: (i) fabricating a transistor and a diode structure on a substrate, wherein: the wafer has the substrate; the transistor has a control gate connected to a word line; and the diode structure has first and second diodes, each diode having a cathode and an anode, wherein the word line is connected to the cathode of the first diode and to the anode of the second diode; and (ii) applying to the wafer a fabrication technique that causes electrical charge to be generated at the transistor, wherein the diode structure provides for the charge one or more dissipation pathways outside of the transistor.

According to yet another embodiment, the present invention is an integrated circuit having (i) an array of flash transistors formed on a substrate and arranged in one or more rows, each flash transistor having a control gate, wherein, in each row, the control gates are connected to a word line; and (ii) for each word line, at least one diode structure formed on the substrate and having first and second diodes, each diode having a cathode and an anode, wherein the word line is connected to the cathode of the first diode and to the anode of the second diode.

### BRIEF DESCRIPTION OF THE DRAWINGS

Other aspects, features, and benefits of the present invention will become more fully apparent from the following detailed description, the appended claims, and the accompanying drawings in which:

FIG. 1 shows a cross-sectional view of a representative flash transistor formed on a p-type silicon substrate;

FIG. 2 graphically illustrates a read operation for the flash transistor of FIG. 1;

FIGS. 3A-B show a diode structure that can be used to reduce detrimental effects of plasma processing on flash transistors such as, but not limited to, the flash transistor of FIG. 1 according to one embodiment of the invention;

FIGS. 4A-B show a diode structure that can be used to reduce detrimental effects of plasma processing on flash transistors such as, but not limited to, the flash transistor of FIG. 1 according to another embodiment of the invention;

FIG. 5 shows a flash-memory circuit according to one embodiment of the invention; and

FIGS. 6A-B show a switch gate that can be used in the flash-memory circuit of FIG. 5 according to one embodiment of the invention.

### DETAILED DESCRIPTION

The problems in the prior art are addressed in accordance with the principles of the present invention by providing charge-dissipation pathways outside of a flash-transistor structure. These pathways advantageously reduce uncontrolled charging of the floating gate and degradation of the adjacent dielectric regions by the electrical charges generated during plasma-processing fabrication steps. One embodiment of the invention provides an integrated circuit having: (i) an array of flash transistors formed on a substrate and arranged in one or more rows, each flash transistor having a control gate, wherein, in each row, the control gates are connected to a word line; and (ii) for each word line, at least one diode structure formed on the substrate and having first and second diodes, each diode having a cathode and an anode, wherein the word line is connected to the cathode of the first diode and to the anode of the second diode. The first and second diodes provide protective charge-dissipation pathways for the flash-transistors connected to the word line.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments.

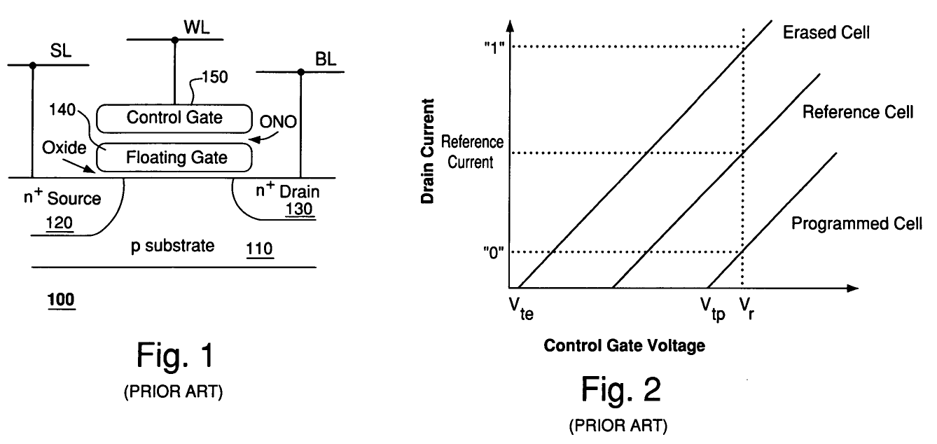

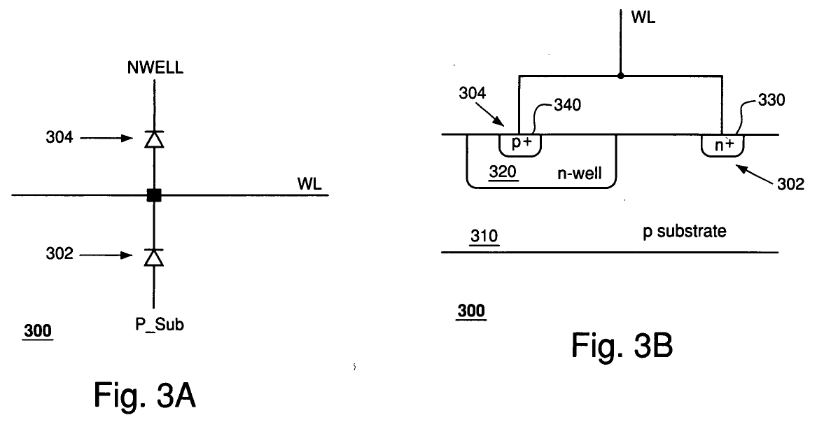

FIGS. 3A-B show a diode structure 300 that can be used to reduce detrimental side effects of plasma processing on, e.g., flash transistor 100 of FIG. 1 according to one embodiment of the invention. More specifically, FIGS. 3A-B show a circuit schematic and a cross-sectional view, respectively, of diode structure 300. Diode structure 300 is implemented on a substrate 310 and includes diodes 302 and 304 coupled to word line WL by the cathode and the anode, respectively. In one embodiment, an IC having an array of flash transistors 100 connected to multiple word lines might have one or more instances of diode structure 300 coupled to each word line.

Referring to FIG. 3B, diode 302 is formed by creating an n-type region 330 on p-type substrate 310, wherein the n-type region and the p-type substrate serve as the cathode and the anode, respectively, of the diode. Diode 304 is formed by first creating an n-type well 320 in p-type substrate 310 and then creating a p-doped region 340 within the n-type well. Well 320 and region 340 serve as the cathode and the anode, respectively, of diode 304. During plasma processing, diodes 302 and 304 provide effective charge dissipation pathways, for both positive and negative charges, outside of the structure of flash transistor 100, which reduces uncontrolled charging of floating gate 140 and degradation of the dielectric regions adjacent to the floating gate. Advantageously, an array of flash transistors 100, in which each word line is protected by at least one diode structure 300, has relatively uniform threshold-voltage characteristics for different flash transistors in the array.

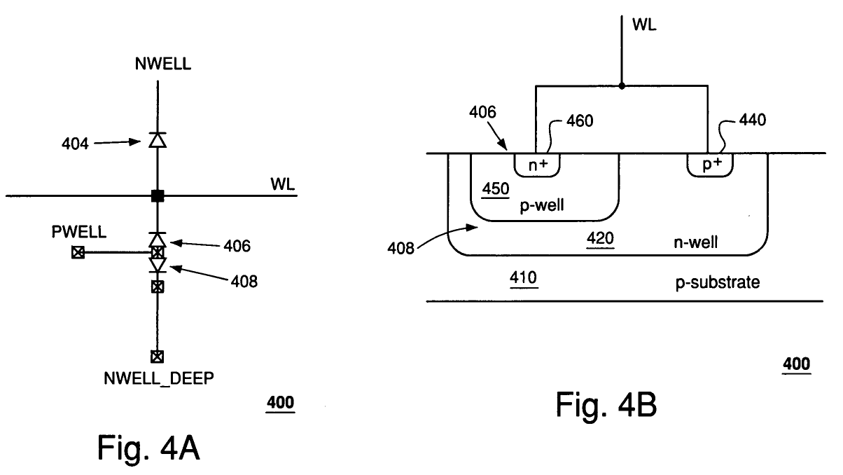

FIGS. 4A-B show a diode structure 400 that can be used to reduce detrimental side effects of plasma processing on, e.g., flash transistor 100 of FIG. 1 according to another embodiment of the invention. More specifically, FIGS. 4A-B show a circuit schematic and a cross-sectional view, respectively, of diode structure 400. Similar to diode structure 300 (FIG. 3), diode structure 400 is implemented on a substrate 410 and includes diodes 404, 406, and 408 coupled to word line WL as shown in FIG. 4A. More specifically, diode 404 is coupled to word line WL by its anode, diode 406 is coupled to word line WL by its cathode, and diode 408 has its anode coupled to the anode of diode 406. In one embodiment, an IC having an array of flash transistors 100 connected to multiple word lines might have one or more instances of diode structure 400 coupled to each word line.

Referring to FIG. 4B, diode 404 is formed by first creating an n-type well 420 in p-type substrate 410 and then creating a p-doped region 440 within the n-type well. Well 420 and region 440 serve as the cathode and the anode, respectively, of diode 404. Diode 408 is formed by creating a p-type well 450 in n-type well 420, with these p- and n-type wells serving as the anode and the cathode, respectively, of diode 408. Diode 406 is formed by creating an n-doped region 460 within p-type well 450. Well 450 and region 460 serve as the anode and the cathode, respectively, of diode 406. Similar to diodes 302 and 304 of diode structure 300, diodes 404, 406, and 408 of diode structure 400 provide effective charge dissipation pathways, for both positive and negative charges, outside of the structure of flash transistor 100. Advantageously, these pathways reduce uncontrolled charging of floating gate 140 and degradation of the dielectric regions adjacent to the floating gate.

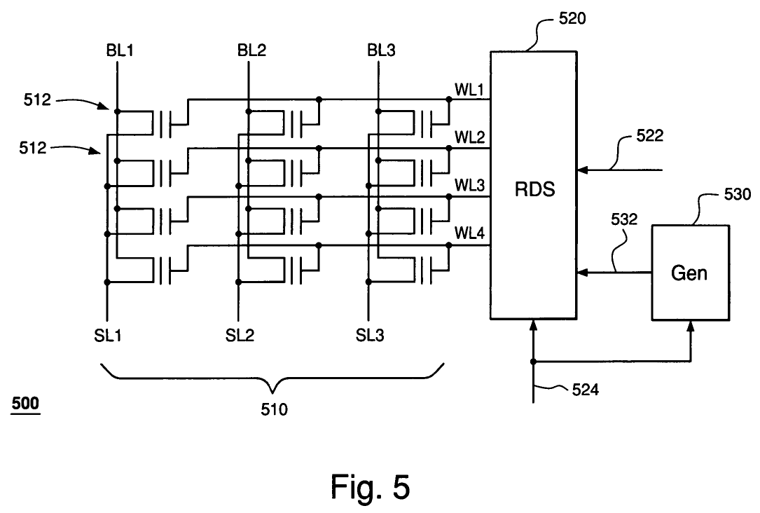

FIG. 5 shows a flash-memory circuit 500 according to one embodiment of the invention. Circuit 500 has an array 510 of flash transistors 512, each of which is analogous to flash transistor 100 of FIG. 1. Flash transistors 512 are arranged in rows and columns, wherein flash transistors in each row are connected to a common word line, and flash transistors in each column are connected to a common bit line and a common source line. For illustration purposes, FIG. 5 shows only four rows and three columns of flash transistors 512 connected to four word lines WL1-WL4, three bit lines BL1-BL3, and three source lines SL1-SL3. The word lines of array 510 are coupled to a row decode and select (RDS) circuit 520, which, in turn, is coupled to a voltage generator 530. In a preferred embodiment, array 510 and RDS circuit 520 are implemented in a single IC. Voltage generator 530 may or may not be a part of that IC.

During a read or program operation, RDS circuit 520 (i) decodes a row address signal 522, which specifies the row number of the memory cell(s) to be accessed (e.g., read from or written to (i.e., programmed)) during that operation, and (ii) applies to the corresponding word line a bias signal 532 produced by voltage generator 530. During an erase operation, RDS circuit 520 ignores row address signal 522 and applies bias signal 532 to all word lines. A control signal 524, which is applied to both RDS circuit 520 and generator 530, specifies the type of operation to be performed, i.e., read, program, or erase. Based on control signal 524, voltage generator 530 selects the bias voltage level to be provided for RDS circuit 520 via bias signal 532, where the value of the bias voltage may depend on the type of operation.

While different physical-device implementations of known or novel circuit schematics of the RDS circuit might be realized, in accordance with one embodiment of the invention, RDS circuit 520 in flash-memory circuit 500 is specifically implemented such that its circuit elements integrally incorporate one or more diode structures analogous to diode structures 300 and/or 400 (FIGS. 3 and 4). Advantageously, flash-memory circuit 500 incorporating such a physical-device implementation of RDS circuit 520 occupies a smaller wafer area than a similar flash memory circuit implemented with “standing-alone” diode structures 300 and/or 400.

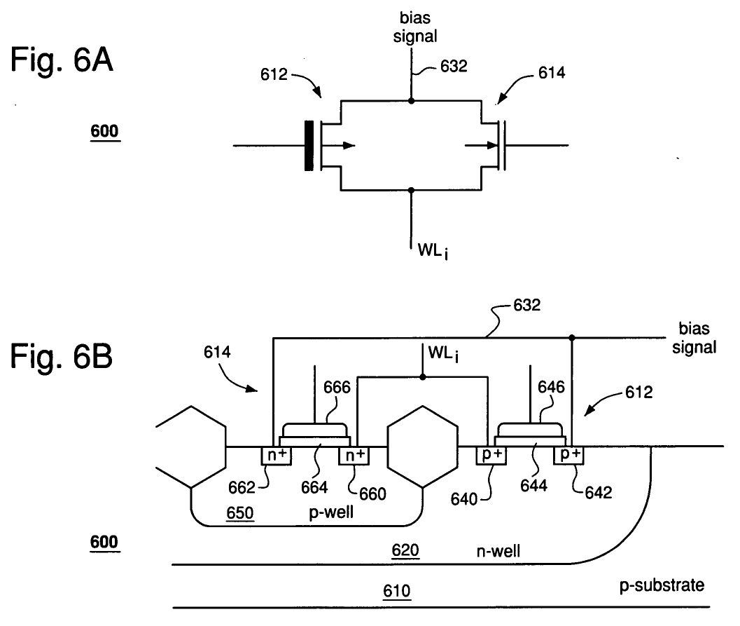

FIGS. 6A-B show a switch gate 600 that can be used in RDS circuit 520 according to one embodiment of the invention. More specifically, FIGS. 6A-B show a circuit schematic and a cross-sectional view, respectively, of switch gate 600. Referring to FIG. 6A, switch gate 600 includes two complementary MOSFET transistors 612 and 614 coupled to a word line WLᵢ and a bias-signal line 632. Transistors 612 and 614 are p- and n-channel transistors, respectively. Implementation of switch gate 600 with complementary transistors 612 and 614 is motivated by the relatively large voltage swing on bias-signal line 632, which can go, for example, from about +10 V for a program operation to about −10 V for an erase operation. Accordingly, p-channel transistor 612 is used to transfer a positive bias voltage from bias-signal line 632 to word line WLᵢ during a program operation, while n-channel transistor 614 is used to transfer a negative bias voltage from the bias-signal line to the word line during an erase operation.

Referring to FIG. 6B, transistor 612 is formed by (i) creating an n-type well 620 in a p-type substrate 610, (ii) creating p-doped regions 640 and 642 within the n-type well to form the source and drain of the transistor, (iii) depositing a thin dielectric layer 644 over portions of the p-doped regions and a portion of the n-type well located between those p-doped regions, and (iv) forming a transistor gate 646 over the dielectric layer. Similarly, transistor 614 is formed by (i) creating a p-type well 650 in n-type well 620, (ii) creating n-doped regions 660 and 662 within the p-type well to form the source and drain of the transistor, (iii) depositing a thin dielectric layer 664 over portions of the n-doped regions and a portion of the p-type well located between those n-doped regions, and (iv) forming a transistor gate 666 over the dielectric layer. Doped regions 640 and 660 are then connected to word line WLᵢ, and doped regions 642 and 662 are connected to bias-signal line 632 to form switch gate 600.

It is apparent from the comparison of FIGS. 4B and 6B that switch gate 600 integrally incorporates a diode structure that is analogous to diode structure 400 of FIG. 4. For example, n-type well 620 and p-doped region 640 form a diode analogous to diode 404 of FIG. 4. Similarly, p-type well 650 and n-type well 620 form a diode analogous to diode 408, and p-type well 650 and n-doped region 660 form a diode analogous to diode 406. Advantageously, the diode structure of switch gate 600 provides effective charge dissipation pathways outside of the flash-transistor array (e.g., array 510 of FIG. 5) while, at the same time, being an integral part of the RDS circuit (e.g., RDS circuit 520) coupled to that array. As a result, diode protection of the word lines can be accomplished while incurring little or no area penalty in the corresponding IC.

In one embodiment, a flash transistor (e.g., analogous to flash transistor 100 of FIG. 1) is protected by a diode structure (e.g., diode structure 400 of FIG. 4) of the invention from possible detrimental effects of plasma processing as follows. First, the transistor and the diode structure are formed on a common substrate. Then, the control gate of the flash transistor and the diode structure are connected to a word line (preferably in metal 1, i.e., the first metal layer formed on the substrate) such that one diode of the diode structure is connected to the word line by the cathode and another diode of the diode structure is connected to the word line by the anode. Finally, a plasma-processing fabrication technique is applied to the wafer, which has the substrate with the transistor and the diode structure on it, e.g., to form various intra-circuit interconnects. Plasma processing causes electrical charge to be generated at and around the flash transistor, while the diode structure provides for that charge alternative dissipation pathways outside of the transistor. These alternative dissipation pathways advantageously reduce uncontrolled charging of the transistor's floating gate and degradation of the adjacent dielectric regions by the flow of the generated charge.

While this invention has been described with reference to illustrative embodiments, this description is not intended to be construed in a limiting sense. Although embodiments of the present invention have been described in reference to flash transistors shown in FIG. 1 and devices fabricated using plasma-processing fabrication steps, the invention can also be practiced with other types of flash transistors, or even non-flash transistors, and/or in the context of a fabrication step other than a plasma-processing step, which step generates electrical charge that can detrimentally affect the transistor structure. For example, instead of a flash-memory cell designed for use with the above-described source-side erase configuration, a flash-memory cell designed for use with a channel-erase configuration (in which a negative voltage is applied to the gate) can also be used. In addition to or instead of the above-described biasing configurations for read, program, and erase operations, other appropriate biasing configurations can be used as known in the art. Although certain embodiments of the present invention have been described in the context of CMOS technology, it will be understood that the present invention can also be implemented using other technologies, such as nMOS, pMOS, or other non-MOS technologies. Various types of diodes such as, for example, antenna (junction) diodes, gated diodes, zener diodes, can be used in diode structures of the invention. Depending on the particular type of flash-memory used in the circuit, diode structures analogous to either diode structure 300 of FIG. 3 or diode structure 400 of FIG. 4, or both types of diode structures can be used. Various modifications of the described embodiments, as well as other embodiments of the invention, which are apparent to persons skilled in the art to which the invention pertains are deemed to lie within the principle and scope of the invention as expressed in the following claims.

Although the acts in the following method claims, if any, are recited in a particular sequence with corresponding labeling, unless the claim recitations otherwise imply a particular sequence for implementing some or all of those acts, those acts are not necessarily intended to be limited to being implemented in that particular sequence.

What is claimed is:

1. An integrated circuit, comprising:
a transistor formed on a substrate and having a control gate connected to a word line; and
a diode structure formed on the substrate and having first and second diodes, each diode having a cathode and an anode, wherein the word line is connected to the cathode of the first diode and to the anode of the second diode.

2. The invention of claim 1, wherein the transistor is a flash transistor.

3. The invention of claim 1, wherein the diode structure is adapted to provide one or more charge-dissipation pathways outside of the transistor.

4. The invention of claim 3, wherein the one or more charge-dissipation pathways are adapted to conduct electrical charges generated when a fabrication technique is applied to a wafer, using which the integrated circuit is fabricated.

5. The invention of claim 3, wherein the one or more charge-dissipation pathways are adapted to reduce charge trapping at a floating gate of the transistor during fabrication of the integrated circuit.

6. The invention of claim 1, wherein:
the first diode comprises a first doped region formed on the substrate, said first doped region connected to the word line; and
the second diode comprises a second doped region formed on a well formed in the substrate, said second doped region connected to the word line.

7. The invention of claim 1, wherein:
the first diode comprises a first doped region formed on a first well, which is formed in a second well formed in the substrate, said first doped region connected to the word line; and
the second diode comprises a second doped region formed on the second well, said second doped region connected to the word line.

8. The invention of claim 7, wherein the diode structure comprises a third diode formed by a portion of the first well and an adjacent portion of the second well.

9. The invention of claim 1, further comprising:
an array of transistors formed on the substrate and arranged in one or more rows, wherein, in each row, the control gates are connected to a common word line; and
one or more instances of the diode structure, wherein each common word line is connected to at least one instance of the diode structure.

10. The invention of claim 9, further comprising a row decode and select (RDS) circuit coupled to the common word lines, wherein, for at least one common word line, the RDS circuit has an instance of the diode structure.

11. The invention of claim 10, wherein, for the at least one common word line, the RDS circuit has a switch gate coupled between the common word line and a bias-signal line, said switch gate having the instance of the diode structure.

12. The invention of claim 11, wherein the switch gate comprises two complementary MOSFET transistors, each coupled (i) to the common word line by a source terminal and (ii) to the bias-signal line by a drain terminal.

13. A method of fabricating an integrated circuit on a wafer, the method comprising:
fabricating a transistor and a diode structure on a substrate, wherein:
the wafer comprises the substrate;
the transistor has a control gate connected to a word line; and
the diode structure has first and second diodes, each diode having a cathode and an anode, wherein the word line is connected to the cathode of the first diode and to the anode of the second diode; and
applying to the wafer a fabrication technique that causes charge to be generated at the transistor, wherein the diode structure provides for the charge one or more dissipation pathways outside of the transistor.

14. The invention of claim 13, wherein the transistor is a flash transistor.

15. The invention of claim 13, wherein the one or more charge-dissipation pathways are adapted to reduce charge trapping at a floating gate of the transistor during fabrication of the integrated circuit.

16. The invention of claim 13, wherein:
the first diode comprises a first doped region formed on the substrate, said first doped region connected to the word line; and
the second diode comprises a second doped region formed on a well formed in the substrate, said second doped region connected to the word line.

17. The invention of claim 13, wherein:
the first diode comprises a first doped region formed on a first well, which is formed in a second well formed in the substrate, said first doped region connected to the word line; and
the second diode comprises a second doped region formed on the second well, said second doped region connected to the word line.

18. An integrated circuit, comprising:
an array of flash transistors formed on a substrate and arranged in one or more rows, each flash transistor having a control gate, wherein, in each row, the control gates are connected to a word line; and
for each word line, at least one diode structure formed on the substrate and having first and second diodes, each diode having a cathode and an anode, wherein the word line is connected to the cathode of the first diode and to the anode of the second diode.

19. The invention of claim 18, further comprising a row decode and select (RDS) circuit formed on the substrate and coupled to the word lines, wherein, for at least one word line, the RDS circuit has the at least one diode structure.

20. The invention of claim 19, wherein, for the at least one word line, the RDS circuit comprises a switch gate coupled between the word line and a bias-signal line, said switch gate having the at least one diode structure.
